(19) United States
(12) Patent Application Publication
(10) Pub. No.: US 2025/0386536 A1
(43) Pub. Date: Dec. 18, 2025

(54) SEMICONDUCTOR DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 19/209,230

(22) Filed: May 15, 2025

(30) Foreign Application Priority Data
Jun. 12, 2024 (JP) 2024-095477

(51) Int. Cl. H10D 30/47; H10D 30/01; H10D 62/85

(52) U.S. Cl. CPC H10D 30/475; H10D 30/015; H10D 62/8503

(57) ABSTRACT

A semiconductor device has a first AlN that is a layer on a substrate or is a AlN substrate. The first AlN includes a lower (0 0 0 1) face and an upper (0 0 0 −1) face. The semiconductor device further has a second group III nitride that includes a lower (0 0 0 1) face and an upper (0 0 0 −1) face. The second group III nitride is disposed on or upward from the first AlN and has a bandgap narrower than that of AlN. The semiconductor device further has a third group III nitride that includes a lower (0 0 0 −1) face and an upper (0 0 0 1) face. The third group III nitride is disposed upward from the second group III nitride, and has a bandgap broader than that of the second group III nitride.

### CROSS-REFERENCE TO RELATED APPLICATION

This application is based upon and claims the benefit of priority of the prior Japanese Patent Application No. 2024-095477, filed on Jun. 12, 2024, the entire contents of which are incorporated herein by reference.

### FIELD

The embodiments discussed herein are related to a semiconductor device.

### BACKGROUND

Gallium nitride (GaN) has high electron saturation velocity and high dielectric breakdown field strength. Accordingly, there is expectation for high electron mobility transistors (HEMT) having a GaN channel layer (hereinafter referred to as “GaN HEMT”) as next-generation power devices having both high voltage withstanding characteristics and high output (e.g., see Japanese Laid-open Patent Publication No. 2012-54352, Japanese Laid-open Patent Publication No. 2013-55148, and Japanese Laid-open Patent Publication No. 2015-115605).

GaN HEMTs having an AlGaN barrier layer (hereinafter referred to as “AlGaN/GaN HEMT”) are already in practical use as power devices. AlGaN/GaN HEMTs are transistors each having only one barrier layer. In contrast with this, transistors each having two AlN barrier layers across a GaN channel layer (hereinafter referred to as “AlN/GaN/AlN transistor”) have been proposed (e.g., see U.S. Pat. No. 7,544,963).

### SUMMARY

According to an aspect of the embodiments, a semiconductor device includes: a first AlN that includes a first lower face that is a (0 0 0 1) face, and a first upper face that is a (0 0 0 −1) face and is disposed upward from the first lower face, the first AlN being a substrate or a group III nitride on a substrate; a second group III nitride that includes a second lower face that is a (0 0 0 1) face, and a second upper face that is a (0 0 0 −1) face and is disposed upward from the second lower face, the second group III nitride having a bandgap that is narrower than a bandgap of AlN, and the second group III nitride being disposed on or upward from the first AlN; and a third group III nitride that includes a third lower face that is a (0 0 0 −1) face, and a third upper face that is a (0 0 0 1) face and is disposed upward from the third lower face, the third group III nitride having a bandgap that is broader than a bandgap of the second group III nitride, and the third group III nitride being disposed upward from the second group III nitride.

Note, however, that the second group III nitride is Inₓ₂Al_{y2}Ga_{1-x2-y2}N (0≤x2≤1−y2, 0≤y2<1). The third group III nitride is Inₓ₃Al_{y3}Ga_{1-x3-y3}N (0≤x3≤1−y3, 0<y3≤1). A plurality of quantum levels are formed in the conduction band of the second group III nitride.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view of an example of a semiconductor device according to a first embodiment.

FIG. 2 is an enlarged view of a portion of FIG. 1 that is surrounded by a dashed line 4.

FIG. 3 is a diagram for describing polarization of each group III nitride layer (i.e., GaN channel layer 8, etc.) in the portion surrounded by the dashed line 4 (see FIG. 1).

FIG. 4 is a diagram illustrating an energy band along line IV-IV in FIG. 3.

FIG. 5 is a diagram for describing operation of the semiconductor device 2.

FIG. 6 is a diagram for describing polarization of an AlN substrate and each of the group III nitride layers that the Comparative Example 1 has.

FIG. 7 is an energy band diagram taken along line VII-VII in FIG. 6.

FIG. 8 is a diagram for describing polarization of an AlN substrate and each of the group III nitride layers that the Comparative Example 2 has.

FIG. 9 is a diagram illustrating an energy band along line IX-IX in FIG. 8.

FIG. 10 is a cross-sectional view of a semiconductor device 302 having a cap layer of other than AlN.

FIG. 11 is a diagram illustrating an energy band of the semiconductor device 302.

FIG. 12 is a cross-sectional view of a semiconductor device 402 having an AlGaN barrier layer 407 between the channel layer 8 and a substrate 6.

FIG. 13 is a diagram illustrating an energy band of the semiconductor device 402.

FIG. 14 is a cross-sectional view of processes, illustrating an example of a manufacturing method of the semiconductor device 402 described with reference to FIGS. 12 and 13.

FIG. 15 is a cross-sectional view of processes, illustrating an example of a manufacturing method of the semiconductor device 402 described with reference to FIGS. 12 and 13.

FIG. 16 is a cross-sectional view of processes, illustrating an example of a manufacturing method of the semiconductor device 402 described with reference to FIGS. 12 and 13.

FIG. 17 is a cross-sectional view of processes, illustrating an example of a manufacturing method of the semiconductor device 402 described with reference to FIGS. 12 and 13.

FIG. 18 is a cross-sectional view of processes, illustrating an example of a manufacturing method of the semiconductor device 402 described with reference to FIGS. 12 and 13.

FIG. 19 is a cross-sectional view of processes, illustrating an example of a manufacturing method of the semiconductor device 402 described with reference to FIGS. 12 and 13.

FIG. 20 is a cross-sectional view of processes, illustrating an example of a manufacturing method of the semiconductor device 402 described with reference to FIGS. 12 and 13.

FIG. 21 is a diagram illustrating a discrete package 44 in which a single semiconductor device according to the first embodiment is encapsulated.

FIG. 22 is a circuit diagram of a high voltage power device 54 that has the semiconductor device according to the first embodiment.

FIG. 23 is a diagram illustrating an example of a PFC circuit 64 that has the high voltage power device 54.

FIG. 24 is a cross-sectional view illustrating an example of the semiconductor device according to the second embodiment.

FIG. 25 is an enlarged view of a portion of FIG. 24 that is surrounded by a dashed line 504.

FIG. 26 is a band diagram taken along line XXVI-XXVI in FIG. 25.

### DESCRIPTION OF EMBODIMENTS

As described previously, AlN/GaN/AlN transistors have been proposed. Energy of conduction band electrons of AlN/GaN/AlN transistors each having a GaN channel layer of a thickness in the order of nanometers (hereinafter referred to as “AlN/GaN/AlN quantum confined transistor”) is quantized. Here, “conduction band electrons” are electrons in a conduction band.

A plurality of quantum levels are formed in the GaN channel layer of AlN/GaN/AlN quantum confined transistors, due to great band offsets between the each AlN barrier layer and the GaN channel layer. Accordingly, with AlN/GaN/AlN quantum confinement transistors, a second quantum level of which mobility is higher than a first quantum level is able to be used for transporting conduction band electrons. Accordingly, with AlN/GaN/AlN quantum confined transistors, there is expectation that higher electron mobility than that of AlGaN/GaN HEMTs is able to be realized.

Note that the first quantum level is a quantum level with the lowest energy of quantum levels formed in a quantum well. The second quantum level is a quantum level with the second lowest energy of quantum levels formed in the quantum well.

Further, with AlN/GaN/AlN quantum confined transistors, conduction band electrons are confined to the channel layer, and accordingly leak current flowing through routes other than the channel layer (e.g., routes passing through regions deeper than the channel layer) is able to be suppressed.

Now, AlN exhibits strong spontaneous polarization. Due to this strong spontaneous polarization, two-dimensional carrier gas is generated in the proximity of an interface between the AlN barrier layer on a substrate side and the GaN channel layer (hereinafter referred to as “substrate-side AlN/GaN interface”). The type of two-dimensional carrier gas that is generated in the proximity of the substrate-side AlN/GaN interface is determined by a crystal plane index of the upper face of a substrate-side AlN barrier layer (e.g., the face in contact with the GaN channel layer).

In a case in which the upper face of the substrate-side AlN barrier face is a (0 0 0 1) face (so-called metal polar face), holes are induced in the GaN channel layer. Accordingly, two-dimensional hole gas is formed in the proximity of the substrate-side AlN/GaN interface. This two-dimensional hole gas inhibits generation of two-dimensional electron gas, and accordingly the GaN channel layer becomes highly resistive.

Conversely, in a case in which the upper face of the substrate-side AlN barrier face is a (0 0 0 −1) face (so-called nitrogen polar face), conduction band electrons are induced in the GaN channel layer, and accordingly, two-dimensional electron gas is formed in high density in the proximity of the substrate-side AlN/GaN interface. However, a strong internal electric field is generated within the GaN channel layer due to the AlN barrier layer on the upper side of the channel layer, hence the two-dimensional electron gas becomes localized, and density and mobility of the two-dimensional electron gas decrease. Thus, the GaN channel layer becomes highly resistive in this case as well.

Embodiments of the present invention will be described hereinafter according to drawings. However, it is noted that the technical scope is not limited to the embodiments described below, but covers the matters described in the claims and the equivalents thereof. Here, identical symbols are given to identical parts even in different drawings, and the description thereof will be omitted.

### First Embodiment

### (1) Structure

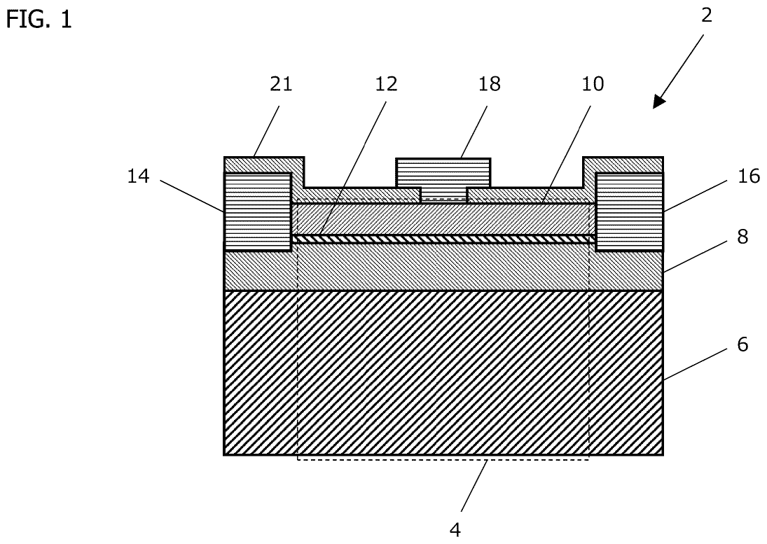

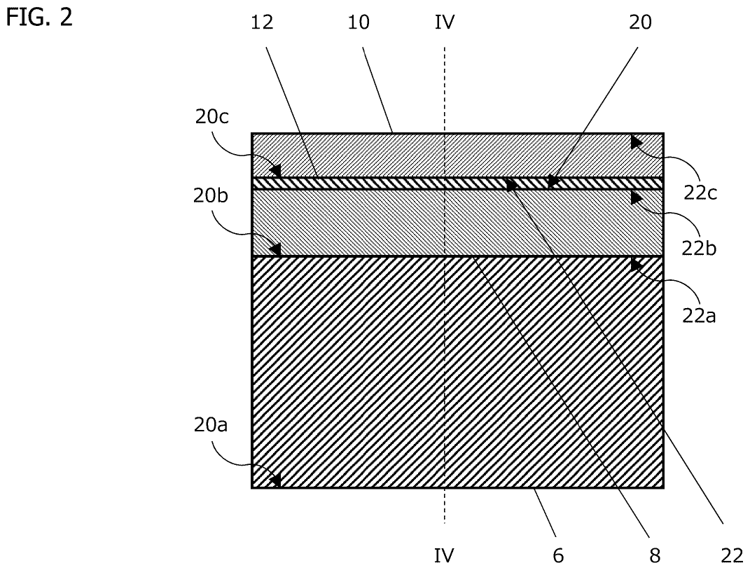

FIG. 1 is a cross-sectional view of an example of a semiconductor device according to a first embodiment (hereinafter referred to as “semiconductor device 2”). FIG. 2 is an enlarged view of a portion of FIG. 1 that is surrounded by a dashed line 4. The semiconductor device 2 has a substrate 6 (see FIG. 2), a channel layer 8 disposed on the substrate 6, and a cap layer 10 disposed upward from the channel layer 8. The semiconductor device 2 further has a polarity inversion layer 12 disposed between the channel layer 8 and the cap layer 10.

The semiconductor device 2 further has a source electrode 14 (see FIG. 1) in contact with the channel layer 8, a drain electrode 16 in contact with the channel layer 8, and a gate electrode 18 that is situated between the source electrode 14 and the drain electrode 16 and that is in contact with the cap layer 10. The semiconductor device 2 further has a passivation film 21 that covers exposed faces of each of the cap layer 10, the source electrode 14, and the drain electrode 16.

The substrate 6 is aluminum nitride (AlN) that has a first lower face 20a (see FIG. 2) that is a (0 0 0 1) face (i.e., metal polar face), and a first upper face 22a that is a (0 0 0 −1) face (i.e., nitrogen polar face) and that is disposed upward from the first lower face 20a. Hereinafter, the substrate 6 will be referred to as “AlN substrate”.

The channel layer 8 is gallium nitride (GaN) that has a second lower face 20b that is a (0 0 0 1) face, and a second upper face 22b that is a (0 0 0 −1) face and that is disposed upward from the second lower face 20b. Hereinafter, the channel layer 8 will be referred to as “GaN channel layer”.

The cap layer 10 is AlN that has a third lower face 20c that is a (0 0 0 −1) face, and a third upper face 22c that is a (0 0 0 1) face and that is disposed upward from the third lower face 20c. Hereinafter, the cap layer 10 will be referred to as “AlN cap layer”.

The polarity inversion layer 12 is an Al film (hereinafter referred to as “Al polarity inversion layer”) has a lower face 20, and an upper face 22 that is disposed upward from the lower face 20. The layer thickness of the Al polarity inversion layer 12 preferably is not less than two atomic layers and not more than four atomic layers. The Al polarity inversion layer 12 may have a different thickness (e.g., not less than two atomic layers and not more than six atomic layers).

### (2) Energy Band

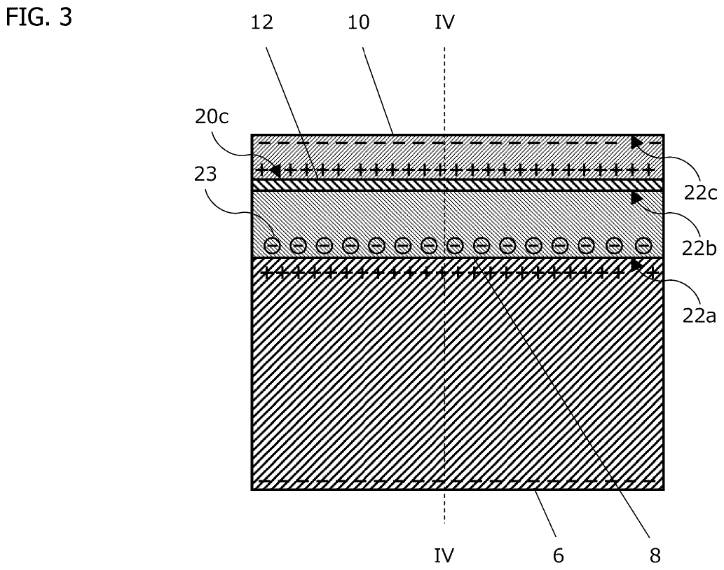

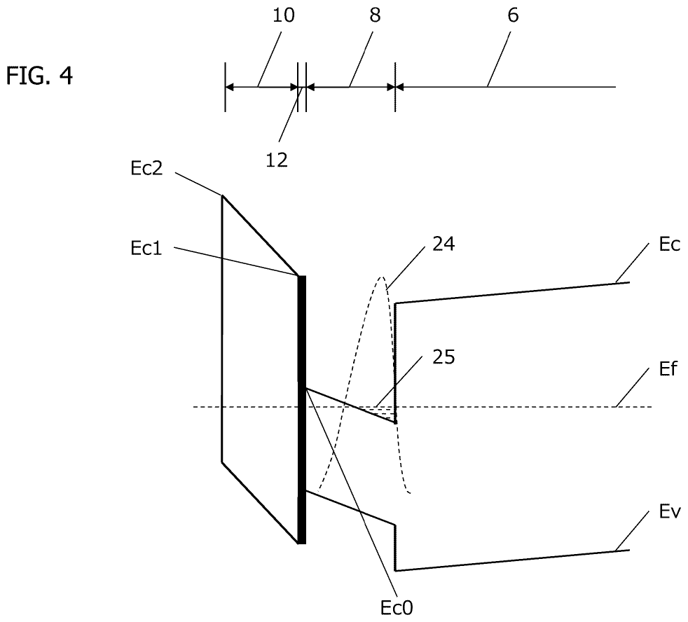

FIG. 3 is a diagram for describing polarization of each group III nitride layer (i.e., GaN channel layer 8, etc.) in the portion surrounded by the dashed line 4 (see FIG. 1). FIG. 4 is a diagram illustrating an energy band along line IV-IV in FIG. 3.

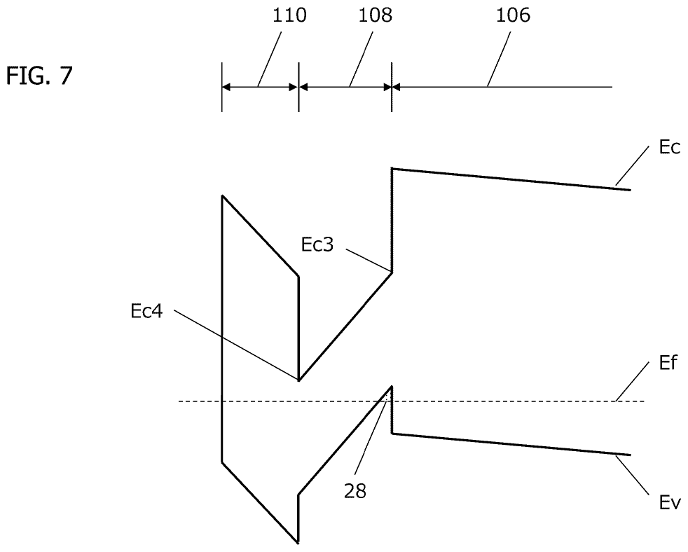

FIG. 4 illustrates a conduction band lower end (i.e. conduction band bottom) Ec of each group III nitride layer, a valence band upper end (i.e. valence band top) Ev of each group III nitride layer, and a Fermi level Ef (likewise in FIG. 7, etc.). The areas that each group III nitride layer and the polarity inversion layer 12 occupy are indicated along with the signs thereof (e.g., “8”) at the top in FIG. 4 (likewise in FIG. 7, etc.).

A bandgap of GaN is narrower than a bandgap of AlN, and accordingly a plurality of quantum levels are formed in the GaN channel layer 8 of nanometer order in thickness that is interposed between the AlN substrate 6 and the AlN cap layer 10. That is to say, the semiconductor device 2 is an AlN/GaN/AlN quantum confined transistor in which a plurality of quantum levels are formed in the conduction band of the GaN channel layer 8. The thickness of the GaN channel layer 8 is, for instance, not less than 5 nm and not more than 20 nm (alternatively, not less than 10 nm and not more than 15 nm).

As described above, the first upper face 22a of the AlN substrate 6 (see FIG. 3) is a nitrogen polar face (i.e., (0 0 0 −1) face). Nitrogen polar faces of group III nitrides such as AlN and so forth are known to charge positively by spontaneous polarization of the AlN or the like. This positive charging induces conduction band electrons 23 in the GaN channel layer 8, and two-dimensional electron gas 25 (see FIG. 4) is formed in the proximity of an interface between the AlN substrate 6 and the GaN channel layer 8 (hereinafter referred to as “substrate-side AlN/GaN interface”).

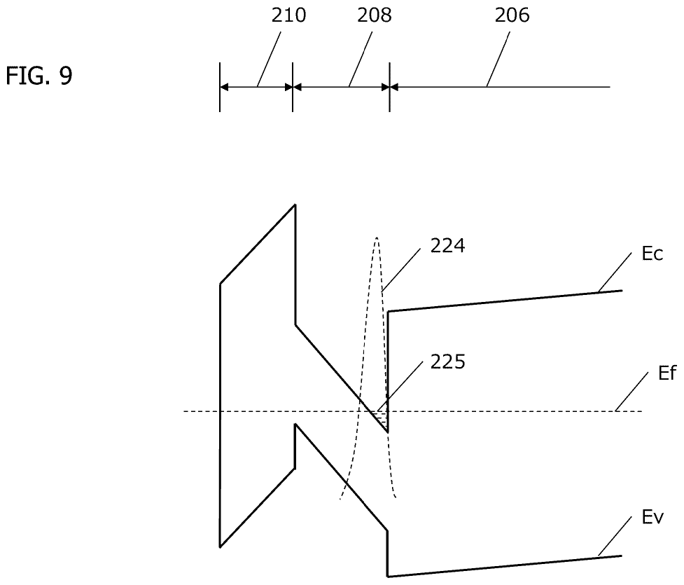

FIG. 4 schematically illustrates a distribution 24 of volume density of the conduction band electrons 23. A horizontal axis (omitted from illustration) is position coordinates in a depth direction. A vertical axis (omitted from illustration) is volume density of the conduction band electrons. The same is true in FIG. 9 and so forth that will be described later.

The third lower face 20c of the AlN cap layer 10 is also a nitrogen polar face that is charged positively (see FIG. 3). Conversely, the third upper face 22c of the AlN cap layer 10 is a metal polar face (i.e., (0 0 0 1) face) that is charged negatively. Accordingly, potential at the third lower face 20c of the AlN cap layer 10 is higher than potential at the third upper face 22c. Accordingly, a conduction band lower end Ec1 at the third lower face 20c of the AlN cap layer 10 (see FIG. 4) is lower than a conduction band lower end Ec2 at the third upper face 22c of the AlN cap layer 10.

As a result, a conduction band lower end Ec0 at the second upper face 22b of the GaN channel layer 8 (see FIG. 4) is lower than a case in which the third lower face 20c of the AlN cap layer 10 is a metal polar face that is charged negatively (hereinafter referred to as “standard arrangement”) (see “(4-2) Comparative Example 2” and FIG. 9).

Hence, inclination of a conduction band lower end Ec at the channel layer 8 is gradual as compared to the case of a standard arrangement (see FIG. 9, described later). Accordingly, the two-dimensional electron gas 25 generated in the proximity of the substrate-side AlN/GaN interface spreads within the GaN channel layer 8, as indicated by the distribution 24 of conduction band electrons (see FIG. 4).

As a result, the peak of the volume density of the two-dimensional electron gas 25 is lower, and accordingly high resistivity of the GaN channel layer 8 (see “(4-2) Comparative Example 2”) is suppressed according to the semiconductor device 2. In other words, resistance of the GaN channel layer 8 is low.

Now, lattice mismatching of the AlN substrate 6 and the GaN channel layer 8 causes strain to occur in the GaN channel layer 8. This strain causes piezoelectric polarization to occur in the GaN channel layer 8. However, this piezoelectric polarization is sufficiently smaller than the spontaneous polarization of the AlN substrate 6 and the AlN cap layer 10, and accordingly is negligible. This is true for the spontaneous polarization of the GaN channel layer 8 as well.

Now, the carrier of the current flowing through the channel layer 8 is electrons. Accordingly, the drain electrode 16 (see FIG. 1) is an electrode that the current flowing through the channel layer 8 passes through before entering the channel layer 8. Conversely, the source electrode 14 is an electrode through which the current which has flowed through the channel layer 8 passes after exiting the channel layer 8. The gate electrode 18 is an electrode that controls the flow of the current flowing through the channel layer 8.

### (3) Operation

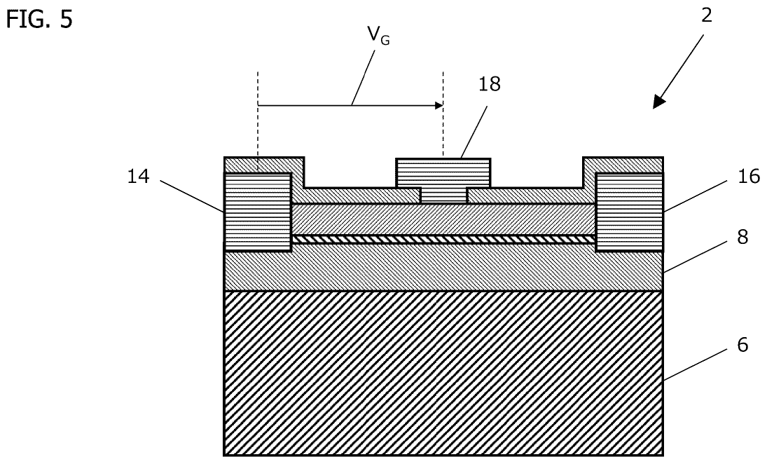

FIG. 5 is a diagram for describing operation of the semiconductor device 2. V_{G} represents potential difference between potential ϕg of the gate electrode 18 and potential ϕs of the source electrode 14 (i.e., ϕg-ϕs). V_{G} is referred to as “gate voltage” hereinafter.

In a case in which the gate electrode 18 is open, the two-dimensional electron gas 25 is present in the channel layer 8 that is directly below the gate electrode 18. This state is maintained even when the gate voltage V_{G} is 0 V or higher.

When the gate voltage V_{G} becomes negative, the conduction band lower end Ec rises within a part of the channel layer 8 immediately below the gate electrode 18, and accordingly concentration of the two-dimensional electron gas 25 decreases there. When the gate voltage V_{G} falls further and becomes smaller than a particular voltage (i.e., a threshold value), the two-dimensional electron gas 25 disappears from the part of the channel layer 8 immediately below the gate electrode 18. As a result, the semiconductor device 2 becomes non-conducting (i.e., off state).

Conversely, in a case in which the gate voltage V_{G} is greater than the threshold value of the semiconductor device 2 (<0 V) or a case in which the gate electrode 18 is open, the two-dimensional electron gas is present in the part of the channel layer 8 immediately below the gate electrode 18. Accordingly, in these cases, the semiconductor device 2 is conducting (i.e., goes to an on state). That is to say, the semiconductor device 2 is a transistor that has normally-on current-voltage characteristics.

### Configuration

The semiconductor device 2 described with reference to FIG. 1 and so forth has the AlN substrate 6. However, the semiconductor device according to the first embodiment may have an AlN layer that has a first lower face that is a (0 0 0 1) face, and a first upper face that is a (0 0 0 −1) face and that is disposed upward from the first lower face, instead of the AlN substrate 6 (see “(5-3) Modification 3”).

That is to say, the semiconductor device according to the first embodiment (see FIG. 1, etc.) has a first AlN that is a group III nitride on a substrate (e.g., AlN layer) or a substrate (e.g., AlN substrate 6). The first AlN has a first lower face that is a (0 0 0 1) face, and a first upper face that is a (0 0 0 −1) face and that is disposed upward from the first lower face.

Also, the semiconductor device 2 (see FIG. 1, etc.) has the GaN channel layer 8. However, the semiconductor device according to the first embodiment may include a layer of a different group III nitride (e.g., InGaN) of which a bandgap is narrower than that of AlN, instead of the GaN channel layer 8.

That is to say, the semiconductor device according to the first embodiment has a second group III nitride that includes a second lower face that is a (0 0 0 1) face, and a second upper face that is a (0 0 0 −1) face and that is disposed upward from the second lower face, the second group III nitride further having a bandgap that is narrower than the bandgap of AlN, and the second group III nitride being disposed on or upward from the first AlN (e.g., AlN substrate 6).

Note, however, that the second group III nitride is different from AlN, which has the broadest bandgap of group III nitrides. Specifically, the second group III nitride is one of InAlGaN, AlGaN, InGaN, InAlN, InN, and GaN. That is to say, the second group III nitride is Inₓ₂Al_{y2}Ga_{1-x2-y2}N (0≤x2≤1−y2, 0≤y2<1).

Note that the x2 and the y2 in the composition formula Inₓ₂Al_{y2}Ga_{1-x2-y2}N of the second group III nitride represent a composition ratio of group III elements in the second group III nitride (likewise in other composition formulae). The inequalities (0≤x2≤1−y2, 0≤y2<1) in parentheses following the above composition formula Inₓ₂Al_{y2}Ga_{1-x2-y2}N indicate ranges that x2 and y2 are capable of taking, respectively (likewise in other inequalities in parentheses).

Also, the semiconductor device 2 (see FIG. 1, etc.) has the Al polarity inversion layer 12. However, the semiconductor device according to the first embodiment may have a different polarity inversion layer that is disposed between the second group III nitride (e.g., GaN channel layer 8) and a later-described third group III nitride (e.g., AlN cap layer 10), instead of the Al polarity inversion layer 12.

Note, however, that the polarity inversion layer is a layer on which a group III nitride (e.g., AlN cap layer 10) including a bottom face that is a (0 0 0 −1) face grows up such that the bottom face comes into contact with the upper face of the polarity inversion layer (see FIG. 2). For instance, AlON, GaON, InON, Al₂O₃, Ga₂O₃, In₂O₃, and mixed crystals of two or more of these, are also polarity inversion layers.

That is to say, the semiconductor device according to the first embodiment includes a polarity inversion layer (e.g., Al polarity inversion layer 12) that has a lower face and an upper face that is disposed upward from this lower face, and that is disposed between the second group III nitride (e.g., GaN channel layer 8) and the third group III nitride (e.g., AlN cap layer 10).

Note, however, that the polarity inversion layer (e.g., Al polarity inversion layer 12) is a layer on which a group III nitride (e.g., AlN cap layer 10) including a bottom face (e.g., third lower face 20c) that is a (0 0 0 −1) face grows up such that the bottom face comes into contact with the upper face of the polarity inversion layer (e.g., upper face 22). The “group III nitride” is, for instance, the third group III nitride (e.g., AlN cap layer 10).

Also, the semiconductor device 2 (see FIG. 1, etc.) has the AlN cap layer 10. However, the semiconductor device according to the first embodiment may include a different group III nitride (e.g., InAlGaN) that has a broader bandgap than the second group III nitride (e.g., GaN), instead of the AlN cap layer 10 (see “(5-1) Modification 1”).

That is to say, the semiconductor device according to the first embodiment includes a third group III nitride that includes the third lower face that is a (0 0 0 −1) face, and a third upper face that is a (0 0 0 1) face and is disposed upward from the third lower face, the third group III nitride having a bandgap that is broader than the bandgap of the second group III nitride, and the third group III nitride being disposed upward from the second group III nitride.

Note, however, that the third group III nitride may be a mixed crystal of AlN, which has the broadest bandgap of group III nitrides, and other group III nitrides (i.e., GaN and InN). Specifically, the third group III nitride is one of InAlGaN, AlGaN, InAlN, and AlN. That is to say, the third group III nitride is Inₓ₃Al_{y3}Ga_{1-x3-y3}N (0≤x3≤1−y3, 0<y3≤1).

According to the above configuration, a plurality of quantum levels are formed in the conduction band of the second group III nitride.

The second group III nitride preferably is Inₓ₂Al_{y2}Ga_{1-x2-y2}N (0≤x2≤ 0.4, 0≤y2≤0.6) (hereinafter referred to as “composition condition 1”). The third group III nitride preferably is Inₓ₃Al_{y3}Ga_{1-x3-y3}N (0≤x3≤0.2, 0.4≤y3≤ 1−x3) (hereinafter referred to as “composition condition 2”).

When the composition condition 1 and the composition condition 2 are satisfied, band discontinuity at the interface between the second group III nitride and the third group III nitride readily becomes great. Further, band discontinuity at the interface between the first AlN and the second group III nitride also readily becomes great. As a result, a plurality of quantum levels are readily formed at the conduction band of the second group III nitride.

The second group III nitride more preferably is Inₓ₂Al_{y2}Ga_{1-x2-y2}N (0≤ x2≤0.2, 0≤y2≤0.3) (hereinafter referred to as “composition condition 3”). The third group III nitride more preferably is Inₓ₃Al_{y3}Ga_{1-x3-y3}N (0≤x3≤0.1, 0.6≤y3≤1−x3) (hereinafter referred to as “composition condition 4”). When the composition conditions 3 and 4 are satisfied, a plurality of quantum levels are more readily formed at the conduction band of the second group III nitride.

The second group III nitride most preferably is Inₓ₂Al_{y2}Ga_{1-x2-y2}N (0≤ x2≤0.1, 0≤y2≤0.2) (hereinafter referred to as “composition condition 5”). The third group III nitride most preferably is Inₓ₃Al_{y3}Ga_{1-x3-y3}N (0≤x3≤0.05, 0.8≤y3≤1−x3) (hereinafter referred to as “composition condition 6”). When the composition conditions 5 and 6 are satisfied, a plurality of quantum levels are even more readily formed at the conduction band of the second group III nitride.

### (4) Comparative Examples

### (4-1) Comparative Example 1

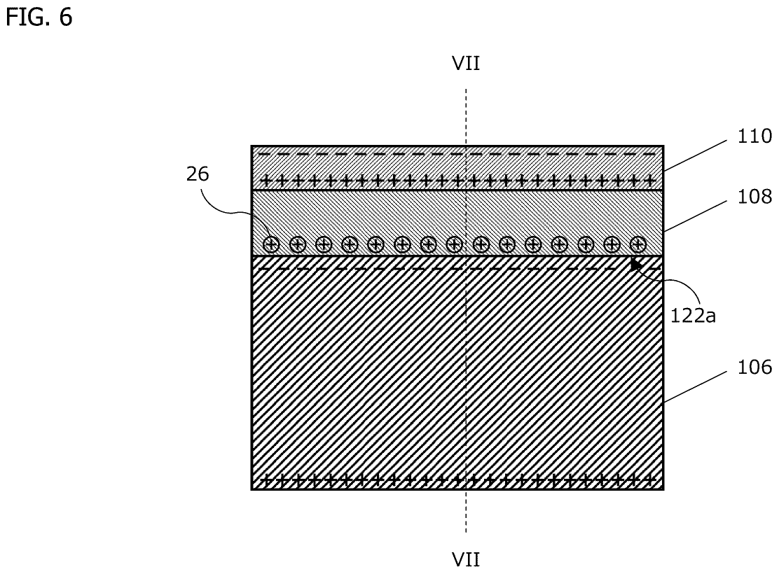

A semiconductor device that has no polarity inversion layer 12 and in which the upper faces of an AlN substrate and each of group III nitride layers are (0 0 0 1) faces (i.e., metal polar faces) (hereinafter referred to as “Comparative Example 1”) will be considered. FIG. 6 is a diagram for describing polarization of an AlN substrate 106 and each of the group III nitride layers 108, 110, which are possessed by the Comparative Example 1. FIG. 7 is an energy band diagram taken along line VII-VII in FIG. 6.

An upper face 122a of the AlN substrate 106 (hereinafter referred to as “substrate upper face”) is a metal polar face (i.e., (0 0 0 1) face), and accordingly is negatively charged due to spontaneous polarization of AlN (see FIG. 6). This negative charging elicits induction of holes 26 in a GaN channel layer 108, and two-dimensional hole gas 28 (see FIG. 7) is formed in the proximity of an interface between the AlN substrate 106 and the GaN channel layer 108 (i.e., substrate-side AlN/GaN interface).

The substrate upper face 122a that is negatively charged makes a conduction band lower end Ec3 of the substrate-side AlN/GaN interface to be higher than within the AlN substrate 106. An electric field that heads from an AlN cap layer 110 toward the AlN substrate 106 (hereinafter referred to as “internal electric field”) is generated in the GaN channel layer 108 due to spontaneous polarization of the AlN cap layer 110 and the AlN substrate 106. As a result, a conduction band lower end Ec4 at an interface between the AlN cap layer 110 and the GaN channel layer 108 (hereinafter referred to as “cap-layer-side AlN/GaN interface”) becomes lower than the conduction band lower end Ec3, which has become higher by internal electric field, at the substrate-side AlN/GaN interface.

However, the GaN channel layer 108 is formed thinly so as to obtain a quantum level, and accordingly the conduction band lower end Ec4 at the cap-layer-side AlN/GaN interface does not drop greatly. Thus, the conduction band lower end Ec4 at the cap-layer-side AlN/GaN interface does not fall below the Fermi level Ef (see “Decrease amount of Conduction Band Lower End in GaN Channel Layer” below).

Accordingly, conduction band electrons are not induced in the GaN channel layer 108, and two-dimensional electron gas is not formed (see FIG. 7). Accordingly, the GaN channel layer 108 becomes highly resistive. Such a problem does not occur with the semiconductor device 2 (see FIG. 2) in which the first upper face 22a of the AlN substrate 6 is a nitrogen polar face (see FIG. 4).

Now, in the example illustrated in FIG. 7, the Fermi level Ef at the upper face of the AlN substrate 106 is away from the middle of a forbidden band. Conversely, the Fermi level Ef within the AlN substrate 106 is almost at the middle of the forbidden band of the AlN. This is true in the semiconductor device 2 according to the first embodiment and a Comparative Example 2 described below as well.

### Decrease Amount of Conduction Band Lower End in GaN Channel Layer

A decrease amount ΔEc (i.e., Ec4−Ec3) of a conduction band lower end Ec due to the internal electric field of the GaN channel layer 108 is a product of an electric field E within the GaN channel layer 108 and a layer thickness d of the GaN channel layer (i.e., −E×d). Accordingly, when the layer thickness d is thinner, the magnitude (i.e., absolute value) of the decrease amount ΔEc is smaller. Note that the unit of energy difference Δ is eV.

### (4-2) Comparative Example 2

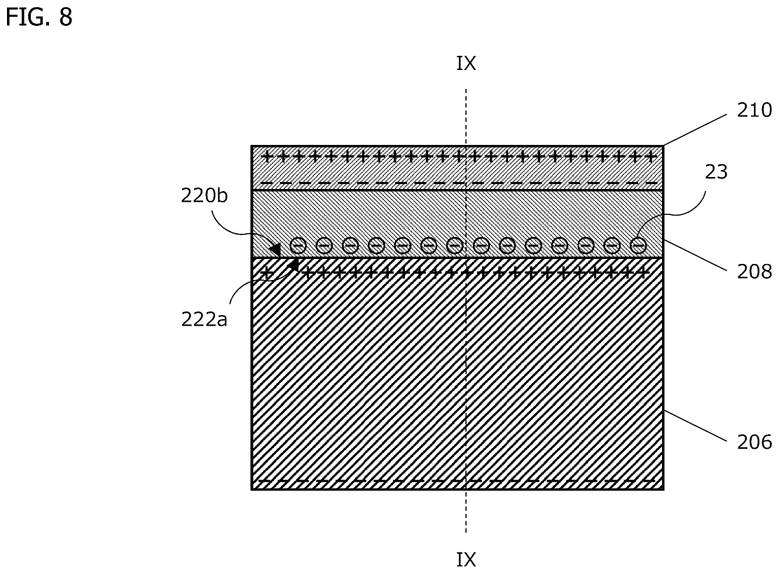

A semiconductor device that has no polarity inversion layer 12 and in which the upper faces of an AlN substrate and each of group III nitride layers are (0 0 0 −1) faces (i.e., nitrogen polar faces) (hereinafter referred to as “Comparative Example 2”) will be considered. FIG. 8 is a diagram for describing polarization of an AlN substrate 206 and each of the group III nitride layers 208, 210, which are possessed by the Comparative Example 2 has. FIG. 9 is a diagram illustrating an energy band along line IX-IX in FIG. 8.

An upper face 222a (see FIG. 8) of the AlN substrate 206 that is a nitrogen polar face (i.e., (0 0 0 −1) face) is positively charged due to spontaneous polarization of the AlN. This positive charging elicits induction of conduction band electrons 23 in a GaN channel layer 208, and two-dimensional electron gas 225 (see FIG. 9) is formed in the proximity of an interface between the AlN substrate 206 and the GaN channel layer 208. Accordingly, two-dimensional electron gas 225 is formed at the GaN channel layer 208 (see FIG. 9) regardless of the thickness of the GaN channel layer 208.

However, an AlN cap layer 210 (see FIG. 8) and the AlN substrate 206 are exhibiting spontaneous polarization in the same direction, and accordingly a strong electric field that heads from the AlN substrate 206 toward the AlN cap layer 210 is generated at the GaN channel layer 208. A conduction band lower end Ec within the GaN channel layer 208 steeply rises toward the AlN cap layer 210 due to this strong electric field (see FIG. 9).

Hence, two-dimensional electron gas 225 with a high concentration is localized in the proximity of the substrate-side AlN/GaN interface, as indicated by a distribution 224 (see FIG. 9) of conduction band electrons. As a result, the concentration (more accurately, volume concentration) of the two-dimensional electron gas 225 becomes excessively high, and accordingly mobility in the GaN channel layer 208 becomes high due to phonon scattering. That is to say, the GaN channel layer 208 becomes highly resistive.

In the semiconductor device 2 described with reference to FIG. 1 and so forth, the conduction band lower end Ec0 (see FIG. 4) at the cap-layer-side AlN/GaN interface is pushed downward by an in-channel-layer electric field heading toward the AlN cap layer 10 (i.e., electric field within the channel layer), and accordingly such a problem does not occur (see FIG. 4).

### (5) Modifications

### (5-1) Modification 1

The cap layer 10 illustrated in FIG. 1 is AlN. However, the cap layer of the semiconductor device according to the first embodiment may be a group III nitride other than AlN.

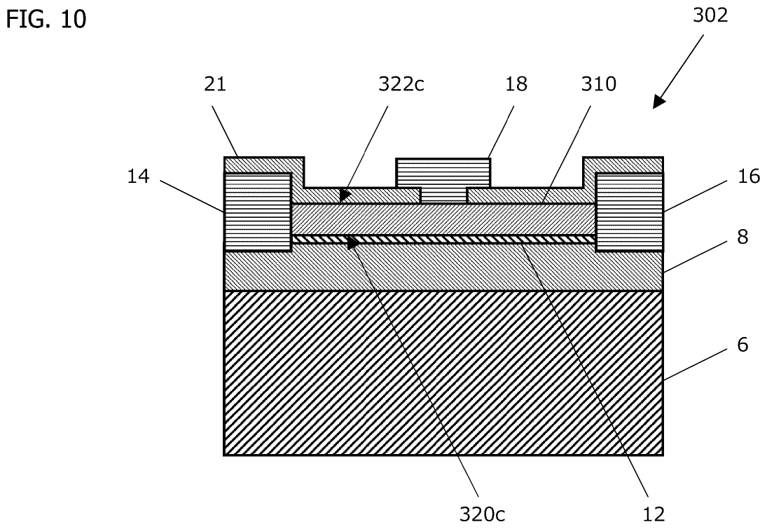

FIG. 10 is a cross-sectional view illustrating an example of such a semiconductor device (hereinafter referred to as “semiconductor device 302”). The semiconductor device 302 has a layer 310 of Inₓ₃Al_{y3}Ga_{1-x3-y3}N (0<x3≤ 0.2, 0<y3≤1−x3) (hereinafter referred to as “InAlGaN cap layer”), instead of the AlN cap layer 10. The cap layer 310 has a third lower face 320c that is a (0 0 0 −1) face, and a third upper face 322c that is a (0 0 0 1) face, in the same way as the AlN cap layer 10. Other than these elements, the semiconductor device 302 has almost the same structure as the semiconductor device 2 described with reference to FIG. 1 and so forth.

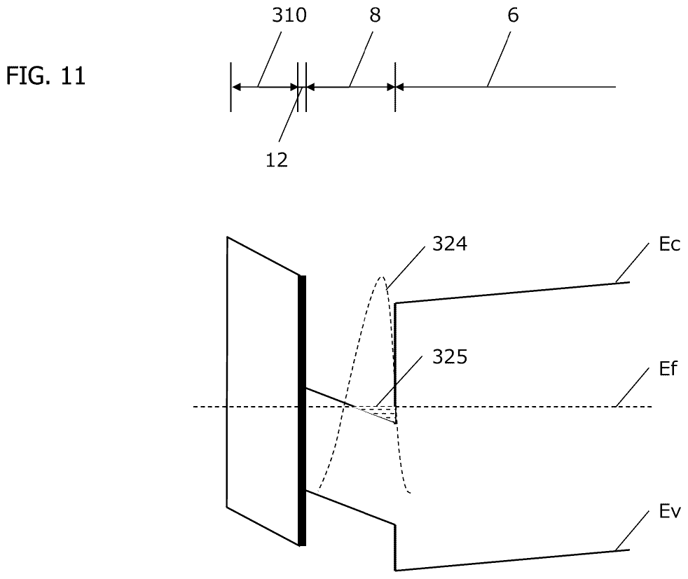

FIG. 11 is a diagram illustrating an energy band of the semiconductor device 302. The InAlGaN cap layer 310 has a bandgap that is broader than the GaN channel layer 8, in the same way as the AlN cap layer 10 (see FIG. 2).

Further, the InAlGaN cap layer 310 exhibits spontaneous polarization in the same direction as the AlN cap layer 10. Accordingly, the inclination of a conduction band lower end Ec in the GaN channel layer 8 is gradual as compared to the Comparative Example 2. As a result, two-dimensional electron gas 325 is broadly distributed within the channel layer 8, which is able to be seen from a distribution 324 of conduction band electrons. Accordingly, the GaN channel layer 8 is suppressed from becoming highly resistive, in the same way as with the semiconductor device 2 described with reference to FIG. 1 and so forth.

In the example described above, the composition ratio y3 of Al is greater than 0 and no greater than 1−x3. However, the composition ratio y3 of Al preferably is no smaller than 0.4 and no greater than 1−x3 (see “Configuration” under “(3) Operation”). In this case, there are hardly any crystal defects occurring in the InAlGaN cap layer 310 due to lattice mismatching with respect to the AlN substrate 6. Accordingly, a situation in which the two-dimensional electron gas 325 is scattered by crystal defects in the InAlGaN cap layer 310 and in which the electrical properties of the GaN channel layer 8 deteriorate as a result of the crystal defects is unlikely to occur.

According to the semiconductor device 302, variations of the semiconductor device according to the first embodiment are increased.

### (5-2) Modification 2

In the semiconductor devices 2 and 302 illustrated in FIGS. 1 and 10, the GaN channel layer 8 is in contact with the AlN substrate 6. However, the semiconductor device according to the first embodiment may have a different layer (hereinafter referred to as “barrier layer”) between the channel layer 8 and the substrate 6.

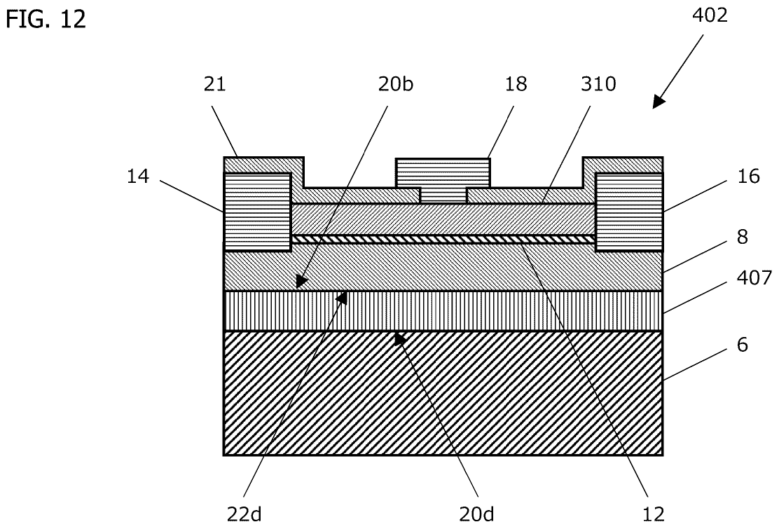

FIG. 12 is a cross-sectional view illustrating an example of such a semiconductor device (hereinafter referred to as semiconductor device 402). The semiconductor device 402 has a layer 407 of Al_{y4}Ga_{1-y4}N (0<y4≤1) (hereinafter referred to as “AlGaN barrier layer”) between the GaN channel layer 8 and the AlN substrate 6. The AlGaN barrier layer 407 has a lower face 20d that is a (0 0 0 1) face (hereinafter referred to as fourth lower face), and an upper face 22d that is a (0 0 0 −1) face (hereinafter referred to as fourth upper face) and that is disposed upward from the fourth lower face 20d. Other than these elements, the semiconductor device 402 has almost the same structure as the semiconductor device 302 (see “(5-1) Modification 1”).

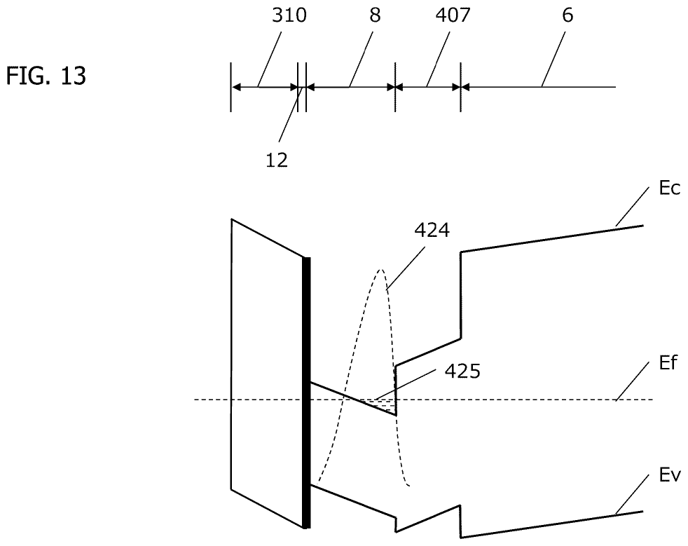

FIG. 13 is a diagram illustrating an energy band of the semiconductor device 402. The AlGaN barrier layer 407 has a bandgap that is broader than the GaN channel layer 8, as illustrated in FIG. 13.

The fourth upper face 22d of the AlGaN barrier layer 407 that is in contact with the GaN channel layer 8 is positively charged by spontaneous polarization of the AlGaN barrier layer 407. This positive charging elicits induction of electrons at the GaN channel layer 8. Accordingly, two-dimensional electron gas 425 (see FIG. 13) is formed in the proximity of an interface between the AlGaN barrier layer 407 and the GaN channel layer 8.

Accordingly, the inclination of a conduction band lower end Ec in the channel layer 8 is gradual, due to the spontaneous polarization of the cap layer 310, in the same way as with the semiconductor device 302 (see “(5-1) Modification 1”) and the semiconductor device 2 (see “(2) Energy Band”). As a result, two-dimensional electron gas 425 is broadly distributed within the channel layer 8, as indicated by a distribution 424 of conduction band electrons. Accordingly, the GaN channel layer 8 is suppressed from becoming highly resistive. According to the semiconductor device 402, variations of the semiconductor device according to the first embodiment are increased.

The semiconductor device 402 described with reference to FIG. 12 and so forth has the AlGaN barrier layer 407. However, the semiconductor device according to the first embodiment may include another group III nitride that has a broader bandgap than the GaN channel layer 8 (e.g., InAlGaN layer), instead of the AlGaN barrier layer 407.

That is to say, the semiconductor device according to the first embodiment may include a fourth group III nitride (e.g., an AlGaN barrier layer or an InAlGaN layer) that is disposed between the first AlN (e.g., AlN substrate 6) and the second group III nitride (e.g., GaN channel layer 8). The fourth group III nitride includes the fourth lower face 20d that is a (0 0 0 1) face and the fourth upper face 22d that is a (0 0 0 −1) face and that is disposed upward from the fourth lower face 20d, the fourth group III nitride further having a bandgap that is broader than the bandgap of the second group III nitride and that is also narrower than the bandgap of AlN.

Note, however, that the fourth group III nitride is a mixed crystal of AlN, which has the broadest bandgap of the group III nitrides, and other group III nitrides (i.e., GaN and InN). Specifically, the fourth group III nitride is one of InAlGaN, AlGaN, InAlN, and AlN. That is to say, the fourth group III nitride is a group III nitride that is expressed by composition formula Inₓ₄Al_{y4}Ga_{1-x4-y4}N (0≤x4≤1−y4, 0<y4≤1).

### (5-3) Modification 3

The semiconductor device 2 described with reference to FIG. 2 and so forth has the AlN substrate 6. However, the semiconductor device according to the first embodiment may have a composited substrate in which an AlN layer is grown on a different substrate (e.g., Si substrate, sapphire substrate, ZnO substrate, monocrystalline diamond substrate, GaN substrate, or Ga₂O₃ substrate), instead of the AlN substrate 6. Note, however, that the AlN layer has a first lower face that is a (0 0 0 1) face, and a first upper face that is a (0 0 0 −1) face and that is disposed upward from the first lower face, in the same way as the AlN substrate 6.

The GaN channel layer 8 is able to be easily suppressed from becoming highly resistive by the semiconductor device 2 that includes the above composited substrate instead of the AlN substrate 6, as well. The AlN layer on the substrate is an example of the first AlN described above (see “Configuration” under “(3) Operation”).

The thickness of the first AlN preferably is not less than 200 nm. The thickness of the first AlN more preferably is not less than 500 nm. The thickness of the first AlN most preferably is not less than 1 μm.

When the thickness of the first AlN is not less than 200 nm, the conduction band lower end Ec at the lower face of the second group III nitride is able to be sufficiently pushed downward by spontaneous polarization of the first AlN. Accordingly, two-dimensional electron gas is more readily generated at the second group III nitride (i.e., channel layer).

### (6) Manufacturing Method

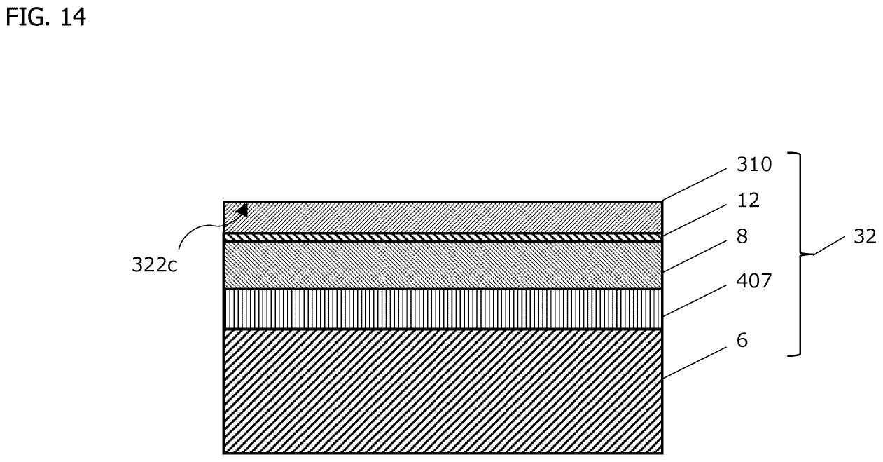

FIGS. 14 to 20 are cross-sectional views of processes, illustrating an example of a manufacturing method of the semiconductor device 402 described with reference to FIGS. 12 and 13.

### (6-1) Growth of Group III Nitride Layers and Polarity Inversion Layer (see FIG. 14)

First, the AlGaN barrier layer 407, the GaN channel layer 8, the Al polarity inversion layer 12, and the InAlGaN cap layer 310 are grown on the nitrogen polar face of the AlN substrate 6, in this order, by metal-organic chemical vapor deposition (see FIG. 14). Growth of the AlGaN barrier layer 407 may be omitted. In this case, the semiconductor device 302 described with reference to FIGS. 10 and 11 is formed.

The AlN substrate 6 is a freestanding substrate. The thickness of the AlGaN barrier layer 407 is, for instance, not less than 25 nm and not more than 100 nm (preferably, 50 nm). The thickness of the GaN channel layer 8 is, for instance, not less than 5 nm and not more than 20 nm (preferably, 10 nm). Alternatively, the thickness of the GaN channel layer 8 is not less than 10 nm and not more than 15 nm. The thickness of the InAlGaN cap layer 310 is, for instance, not less than 5 nm and not more than 20 nm (preferably, 10 nm).

A source material gas for the AlGaN barrier layer 407 and so forth is a mixed gas of one, or two or more metalorganic gases including a group III element, and ammonia (NH₃) gas. For example, the above metalorganic gases include one or a plurality of trimethyl aluminum (TMAI) gas, trimethyl gallium (TMGa) gas, and trimethyl indium (TMI) gas. The carrier gas is hydrogen (H₂) gas or nitrogen (N₂) gas. Growth pressure is, for instance, 1 kPa to 100 kPa. Growth temperature is, for instance, 600° C. to 1500° C.

The Al polarity inversion layer 12 is formed by temporarily supplying trimethyl aluminum gas instead of the mixed gas, following growth of the GaN channel layer 8. Thereafter, supply of the mixed gas is restarted, thus growing the InAlGaN cap layer 310 having the third upper face 322c that is a metal polar face. The growth temperature of InAlGaN is lower than that of AlN, and accordingly the InAlGaN cap layer 310 is able to be grown without raising the growth temperature following growing the GaN channel layer 8.

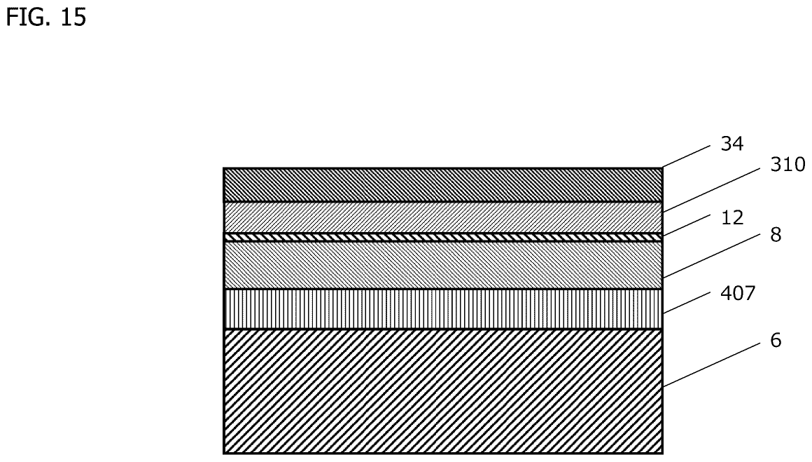

### (6-2) Formation of Source Electrode 14 and Drain Electrode 16 (See FIGS. 15 to 17)

### Formation of Device Isolation Grooves

Next, a plurality of layers 32 (see FIG. 14) grown on the AlN substrate 6 are etched to form device isolation grooves (omitted from illustration) that reach the AlN substrate 6. The plurality of layers 32 will be referred to as “grown layers” hereinafter.

First, a photoresist film that has grid-like openings (omitted from illustration) is formed on the InAlGaN cap layer 310 (see FIG. 14). These openings have almost the same shape and dimensions as the device isolation grooves in plain view.

The grown layers 32 are etched via the openings to form the device isolation grooves (omitted from illustration). Dry etching is used for etching of the grown layers 32. The etching gas is a chlorine-based gas, for instance. The photoresist film is then removed. In-between regions that will separate the semiconductor devices 402 may be made to be highly resistive by ion implantation, instead of forming the device isolation grooves.

### Formation of Surface Protective Film 34

Next, a surface protective film 34 (see FIG. 15) is formed on the InAlGaN cap layer 310 by plasma chemical vapor deposition (hereinafter referred to as “plasma CVD”), for instance. The surface protective film 34 may be formed by atomic layer deposition (hereinafter referred to as “ALD”) or sputtering.

The surface protective film 34 preferably is a SiO₂ film. The surface protective film 34 may be an oxide of one of Al, Hf, Zr, Ti, Ta, and W. Alternatively, the surface protective film 34 may be a nitride (or oxynitride) of one of Si, Al, Hf, Zr, Ti, Ta, and W.

### Etching of Grown Layers

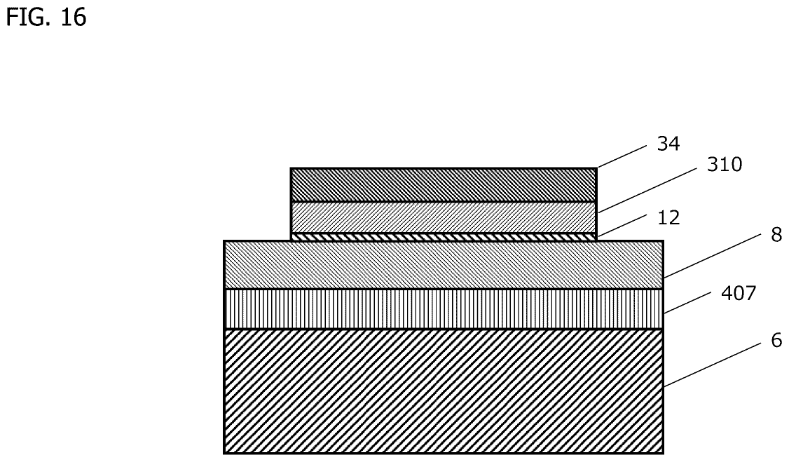

Next, a photoresist film that has openings (hereinafter referred to as “first openings”) in an areas where the source electrode 14 is to be formed and another area where the drain electrode 16 is to be formed, is formed on the surface protective film 34. Thereafter, the surface protective film 34 and the grown layers 32 are etched via the first openings until the GaN channel layer 8 is exposed (see FIG. 16). At this time, the GaN channel layer 8 is over etched, in order to expose the GaN channel layer 8 in a sure manner.

Dry etching is used for etching of the surface protective film 34 and the grown layers 32. The etching gas is a chlorine-based gas, for instance. The photoresist film having the first openings is then removed.

### Formation of Electrodes

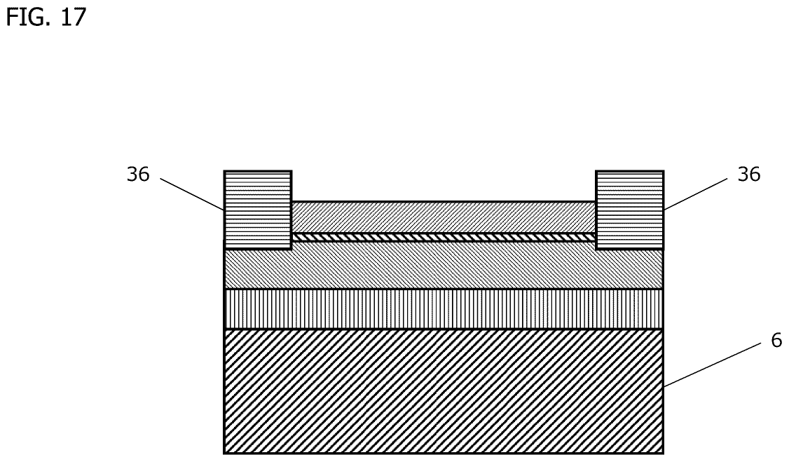

Next, a bi-layer film 36 having a Ta film that comes into contact with the GaN channel layer 8 and an Al film that comes into contact with this Ta film (hereinafter referred to as “Ta/Al film”), is formed in recesses formed by the above etching (see FIG. 17). The Ta/Al film 36 is formed by lift-off, for instance. The thickness of the Ta film is not less than 10 nm and not more than 40 nm (preferably 20 nm), for instance. The thickness of the Al film is not less than 100 nm and not more than 400 nm (preferably 200 nm), for instance.

Next, the AlN substrate 6, above which the Ta/Al film 36 is formed, is heated in a nitrogen atmosphere. The heating temperature is no lower than 400° C. and no higher than 1000° C. (preferably 550° C.). Ohmic contacts are formed between the Ta/Al film 36 and the GaN channel layer 8 by this heating. Accordingly, the source electrode 14 and the drain electrode 16 are completed.

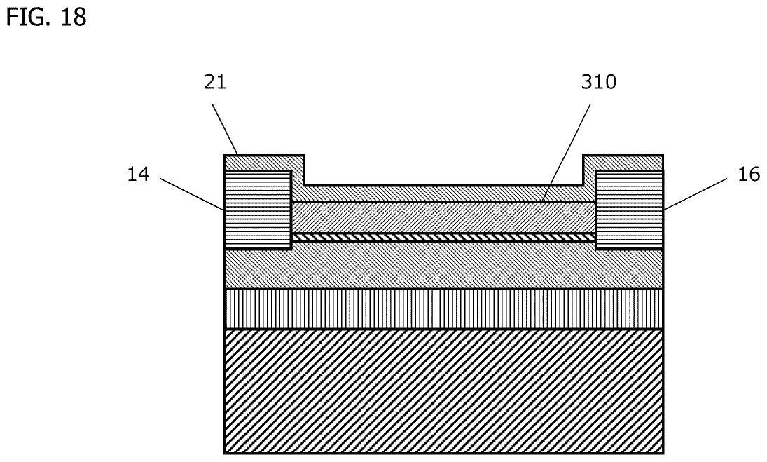

### (6-3) Formation of Passivation Film 21 (see FIG. 18)

Next, the passivation film 21 that covers the InAlGaN cap layer 310, the source electrode 14, and the drain electrode 16, is formed by plasma CVD, for instance (see FIG. 18). The thickness of the passivation film 21 is not less than 2 nm and not more than 500 nm (preferably 100 nm), for instance. The passivation film 21 may be formed by sputtering or ALD. The passivation film 21 preferably is a SiN film. The passivation film 21 may be a nitride of one of Al, Hf, Zr, Ti, Ta, and W. Alternatively, the passivation film 21 may be an oxide (or oxynitride) of one of Si, Al, Hf, Zr, Ti, Ta, and W.

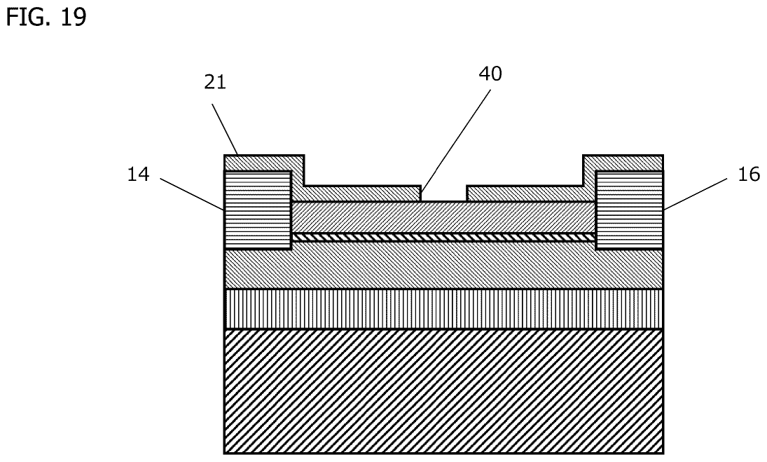

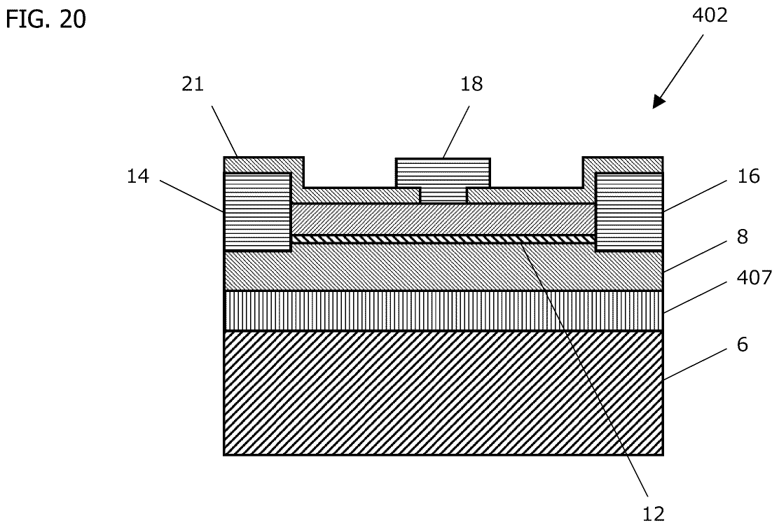

### (6-4) Formation of Gate Electrode 18 (See FIGS. 19 and 20)

Next, a photoresist film having an opening between the source electrode 14 and the drain electrode 16 (hereinafter referred to as “second opening”) is formed on the passivation film 21. Thereafter, the passivation film 21 is etched via the second opening (see FIG. 19). Due to this etching, an opening 40 (hereinafter referred to as “gate opening”) is formed in the passivation film 21.

Dry etching is used for etching of the passivation film 21. The etching gas is a fluorine-based gas or a chlorine-based gas, for instance. The photoresist film is then removed. Etching of the passivation film 21 may be performed by wet etching. The etchant is hydrofluoric acid or buffered hydrofluoric acid, for instance.

Next, the gate electrode 18 is formed within the gate opening 40, having an Ni film in contact with the InAlGaN cap layer 310 and an Au film in contact with this Ni film (FIG. 20). The gate electrode 18 is formed by lift-off, for instance.

The thickness of the Ni film is not less than 15 nm and not more than 60 nm (preferably 30 nm), for instance. The thickness of the Au layer is not less than 200 nm and not more than 800 nm (preferably 400 nm), for instance. Thus, the semiconductor device 402 is completed.

As described above, the manufacturing method of the semiconductor device according to the first embodiment has a first process of growing the second group III nitride (see “Configuration” under “(3) Operation”) on or upward from the (0 0 0 −1) face of the first AlN.

The manufacturing method of the semiconductor device according to the first embodiment further has a second process of growing the polarity inversion layer that has the lower face and the upper face disposed upward from the lower face, on the second group III nitride (e.g., GaN channel layer 8), following the first process.

The manufacturing method of the semiconductor device according to the first embodiment further has a third process of growing the third group III nitride (see “Configuration” under “(3) Operation”) on the polarity inversion layer (e.g., Al polarity inversion layer 12), following the second process.

The manufacturing method of the semiconductor device according to the first embodiment further has a fourth process of forming electrodes (e.g., source electrode 14, drain electrode 16, and gate electrode 18), following the third process.

Note, however, that the second group III nitride is Inₓ₂Al_{y2}Ga_{1-x2-y2}N (0≤x2≤1−y2, 0≤y2<1). The third group III nitride is Inₓ₃Al_{y3}Ga_{1-x3-y3}N (0≤ x3≤ 1−y3, 0<3<1). The polarity inversion layer is a substance on which a group III nitride (at least the third group III nitride) grows which has a (0 0 0 −1) face that comes in contact with the upper face of the polarity inversion layer.

### (7) Usage Examples

### (7-1) Usage Example 1

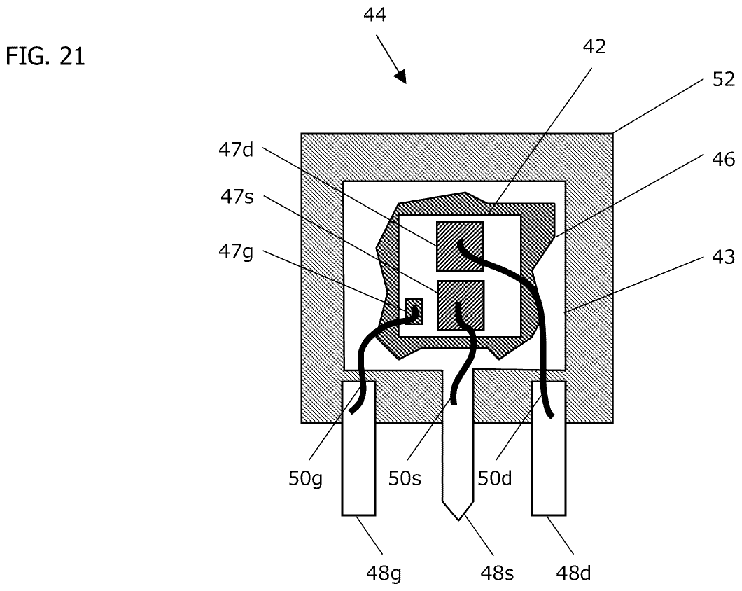

The semiconductor device according to the first embodiment is able to be used as a discrete device. FIG. 21 is a diagram illustrating a discrete package 44 in which a single semiconductor device according to the first embodiment is encapsulated. The discrete package 44 is an example of a discrete device.

A structure of the discrete package 44 will be described below in accordance with a manufacturing method thereof. First, a die 42 (i.e., chip) is fixed to a die pad 43 by a die attaching agent 46 such as solder or the like. The die 42 has, for instance, the semiconductor device 302 (see FIG. 10), a gate pad 47g that is connected to the gate electrode 18, a source pad 47s that is connected to the source electrode 14, and a drain pad 47d that is connected to the drain electrode 16. The gate pad 47g is an electrode that is disposed on the passivation film 21 (see FIG. 10). This also holds regarding the source pad 47s and the drain pad 47d.

Thereafter, a gate lead 48g and the gate pad 47g are connected by a bonding wire 50g. Further, a source lead 48s and the source pad 47s are connected by a bonding wire 50s. Moreover, a drain lead 48d and the drain pad 47d are connected by a bonding wire 50d.

Thereafter, the die 42 is encapsulated by a molding resin 52. FIG. 21 partially illustrates the molding resin 52, such that the die 42 and so forth are visible. Encapsulation is performed by transfer molding, for instance.

Finally, the gate lead 48g, the source lead 48s, the drain lead 48d, and the die pad 43 are cut loose from a lead frame (omitted from illustration). Thus, the discrete package 44 is completed.

### (7-2) Usage Example 2

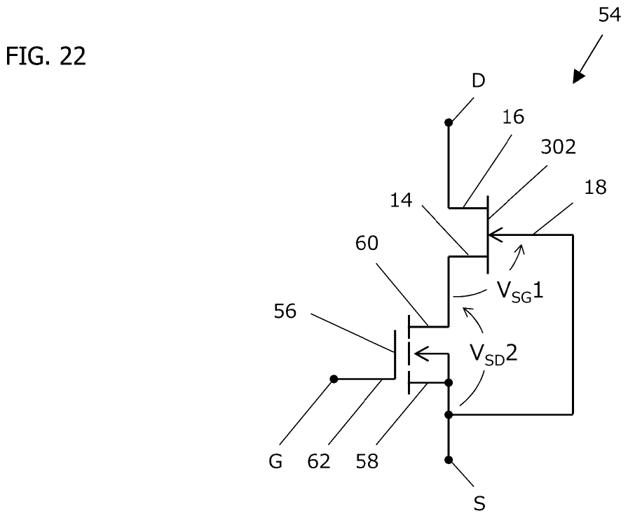

The semiconductor device according to the first embodiment is able to also be used in combination with other semiconductor devices. FIG. 22 is a circuit diagram of a high voltage power device 54 that has the semiconductor device according to the first embodiment. In addition to characteristics that the semiconductor device according to the first embodiment has (i.e., high voltage withstanding characteristics), this high voltage power device 54 also has normally-off characteristics, which the semiconductor device according to the first embodiment does not have.

Normally-off characteristics are important characteristics for power devices. When a gate driver that controls a power device with a normally-on characteristics (hereinafter referred to as “normally-on device”) fails, overcurrent flows to the normally-on device. As a result, the circuit that is equipped with the normally-on device may be damaged.

Conversely, when a gate driver that controls a power device with a normally-off characteristics (hereinafter referred to as “normally-off device”) fails, the normally-off device becomes non-conductive. As a result, the circuit that is equipped with the normally-off device is spared from being damaged by overcurrent. Hence, normally-off characteristics are important characteristics for power devices.

The high voltage power device 54 illustrated in FIG. 22 has the semiconductor device 302 described with reference to FIG. 10, and a silicon low voltage metal-oxide-semiconductor field-effect transistor (MOSFET) 56 (hereinafter referred to as “LV-MOSFET”). An LV-MOSFET is a MOSFET that has a positive threshold value (>0 V). The high voltage power device 54 may have another semiconductor device according to the first embodiment (e.g., semiconductor device 2) instead of the semiconductor device 302.

The LV-MOSFET 56 is an n-channel MOSFET that has a source electrode 58 that is connected to the gate electrode 18 (see FIG. 10) of the semiconductor device 302, a drain electrode 60 that is connected to the source electrode 14 of the semiconductor device 302, and a gate electrode 62.

The high voltage power device 54 further has a source terminal S that is connected to the source electrode 58 of the LV-MOSFET 56, a gate terminal G that is connected to the gate electrode 62 of the LV-MOSFET 56, and a drain terminal D that is connected to the drain electrode 16 of the semiconductor device 302. A control signal that controls on/off of the high voltage power device 54 is applied between the gate terminal G and the source terminal S. The control signal is applied by a gate driver (omitted from illustration).

Source-gate voltage V_{SG}1 of the semiconductor device 302 is equal to voltage obtained by reversing the sign of the source-drain voltage V_{SD}2 of the LV-MOSFET 56 (i.e., −V_{SD}2), which is able to be understood from FIG. 22. The source-gate voltage V_{SG}1 is the gate voltage V_{G} described with reference to FIG. 5.

When voltage that is higher than the positive threshold value (>0 V) of the LV-MOSFET 56 is applied between the source electrode 58 and the gate electrode 62 of the LV-MOSFET 56, the LV-MOSFET 56 conducts. The source-drain voltage V_{SD}2 of the LV-MOSFET 56 then becomes almost 0 V, and accordingly the source-gate voltage V_{SG}1 (i.e., −V_{SD}2) of the semiconductor device 302 also becomes almost 0 V. As a result, the semiconductor device 302 that has normally-on characteristic conducts as well. Thus, the high voltage power device 54 conducts (i.e., goes to on).

Conversely, when voltage that is lower than the positive threshold value (>0 V) of the LV-MOSFET 56 is applied between the source electrode 58 and the gate electrode 62 of the LV-MOSFET 56, the LV-MOSFET 56 becomes non-conducting. The source-drain voltage V_{SD}2 of the LV-MOSFET 56 then rises and becomes positive, and the source-gate voltage V_{SG}1 (i.e., −V_{SD}2) of the semiconductor device 302 becomes negative.

The device parameters of each of the semiconductor device 302 and the LV-MOSFET 56 are designed such that the source-gate voltage V_{SG}1 (see FIG. 22) at this time is smaller than the negative threshold value (<0 V) of the semiconductor device 302. Accordingly, when the LV-MOSFET 56 becomes non-conducting, the semiconductor device 302 also becomes non-conducting. As a result, the high voltage power device 54 becomes non-conducting (i.e., goes to off).

When voltage that is higher than the positive threshold value (>0 V) of the LV-MOSFET 56 is applied between the source terminal S and the gate terminal G, the high voltage power device 54 conducts, which is able to be understood from the above description. Conversely, when voltage that is lower than the positive threshold value (>0 V) of the LV-MOSFET 56 is applied between the source terminal S and the gate terminal G, the high voltage power device 54 becomes non-conducting. That is to say, the high voltage power device 54 has normally-off characteristics.

Further, the semiconductor device 302 has high voltage withstanding characteristics, and accordingly the voltage withstanding characteristics of the high voltage power device 54 become higher. That is to say, the high voltage power device 54 has normally-off characteristics, and the high voltage withstanding characteristics of the semiconductor device 302.

### (7-3) Usage Example 3

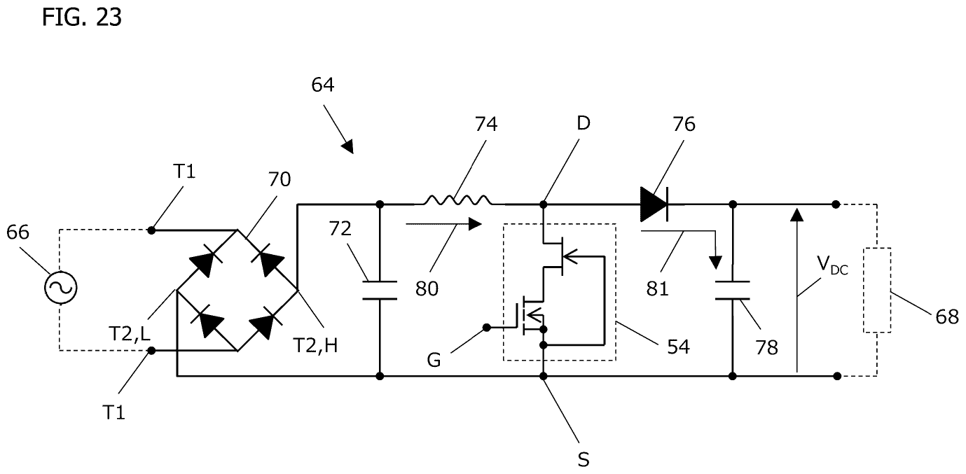

The high voltage power device 54 (FIG. 22) is favorable for use as a switching device in an active power factor correction circuit (hereinafter referred to as “PFC circuit”). FIG. 23 is a diagram illustrating an example of a PFC circuit 64 that has the high voltage power device 54.

The PFC circuit 64 is a power source circuit that converts alternating current voltage supplied from an alternating current power source 66 into direct current voltage, and supplies the converted voltage to a load 68. As illustrated in FIG. 23, the PFC circuit 64 has a diode bridge 70 that has a pair of input terminals T1 (hereinafter referred to as “bridge input terminals”) and a pair of output terminals T2 (hereinafter referred to as “bridge output terminals”), and a capacitor 72 that is connected to the bridge output terminals T2. The alternating current power source 66 is connected to the bridge input terminals T1.

The PFC circuit 64 further has a choke coil 74 of which one end is connected to one of the bridge output terminals T2 (hereinafter referred to as “high terminal H”). The PFC circuit 64 further has the high voltage power device 54 of which the drain terminal D is connected to the other end of the choke coil 74, and the source terminal S is connected to the other of the bridge output terminals T2 (hereinafter referred to as “low terminal L”). A gate driver (omitted from illustration) is connected between the gate terminal G and the source terminal S of the high voltage power device 54.

The PFC circuit 64 further has a diode 76 of which an anode terminal is connected to the drain terminal D of the high voltage power device 54. The PFC circuit 64 further has a capacitor 78 (hereinafter referred to as “output capacitor”) of which one end is connected to a cathode terminal of the diode 76 and the other end thereof is connected to the low terminal L (i.e., the other of the bridge output terminals T2).

A current 81 is supplied to the output capacitor 78 via the diode 76. The output capacitor 78 is charged by this current 81 (hereinafter referred to as “charging current”). Direct current voltage is then generated between both ends of the output capacitor 78. This direct current voltage is applied to the load 68.

The diode 76 serves to rectify, and accordingly the charging current 81 flows only as long as the potential at the anode side is higher than the potential at the cathode side. When application of alternating current voltage to the PFC circuit 64 starts, the direct current voltage V_{DC} that is generated between both ends of the output capacitor 78 gradually increases. Accordingly, immediately after starting supply of the alternating current voltage, the charging current 81 flows for a period that is the greater part of one cycle of the alternating current voltage. However, when the direct current voltage V_{DC} becomes higher with passage of time, the period during which the charging current 81 flows gradually becomes shorter.

Now a circuit in which the high voltage power device 54 and the choke coil 74 are omitted from the PFC circuit 64 will be considered. However, the choke coil 74 is replaced by a conducting line, in order to secure a current path from the high terminal H (i.e., the one of the bridge output terminals T2) to the diode 76. A waveform of the charging current 81 flowing over this circuit will be greatly different from a voltage waveform of the alternating current power source 66 (e.g., sine wave), due to rectifying effects of the diode bridge 70 and the diode 76. For instance, the charging current 81 is a current that flows intermittently.

Next, a circuit in which just the high voltage power device 54 is omitted from the PFC circuit 64 (i.e., passive PFC circuit) will be considered. The waveform of the charging current 81 flowing over this circuit becomes more continuous due to the inductivity of the choke coil 74, and nears the waveform of the alternating current moderately. However, there remains a non-negligible difference between the voltage waveform of the alternating current power source 66 and the waveform of the charging current 81.

Accordingly, a power factor of the alternating current power source 66 is not very high. Moreover, the current that the alternating current power source 66 outputs will have a great high-frequency component. In other words, the alternating current power source 66 will emit a great high-frequency noise.

Finally, a case of turning on the high voltage power device 54 as appropriate in the PFC circuit 64 will be considered. As long as current 80 flowing to the choke coil 74 (hereinafter referred to as “choke coil current”) is almost the same waveform as a full-wave rectified waveform, the power factor of the alternating current power source 66 will be substantially 1, even if the waveform of the charging current 81 and the voltage waveform of the alternating current power source 66 are different. Note that a full-wave rectified waveform is a waveform obtained by inverting a sine wave in the latter half of each one cycle (i.e., negative portion of sine wave).

The choke coil current 80 is the sum of the charging current 81 flowing at the diode 76 and the current flowing at the high voltage power device 54. Accordingly, turning on the high voltage power device 54 in a timely manner enables the choke coil current 80 to be brought closer to a full-wave rectified waveform. Thus, turning on the high voltage power device 54 in a timely manner enables improvement of the power factor and decrease of high-frequency noise to be achieved.

Note, however, that it is important that the high voltage power supply 54 operates at high speed (hereinafter referred to as “Request 1”), in order to bring the waveform of the choke coil current 80 close to a full-wave rectified waveform.

Also, it is also important that loss of the high voltage power device 54 is small (hereinafter referred to as “Request 2”), in order to further improve the power factor. That is to say, low on-resistance of the high voltage power device 54 is important.

The high voltage power device 54 is able to satisfy these Requests 1 and 2, due to high mobility of the semiconductor device 302. Accordingly, the high voltage power device 54 is favorable as a switching device for the PFC circuit. Also, the withstanding characteristics of the high voltage power device 54 are high, and accordingly the direct current voltage V_{DC} (i.e., output voltage of PFC circuit 64) is able to be raised.

The direction of spontaneous polarization of the first AlN (e.g., AlN substrate 6) and the direction of spontaneous polarization of the third group III nitride (e.g., AlN cap layer 10) are opposite to each other in the semiconductor device according to the first embodiment, as described with reference to FIG. 3 and so forth. Accordingly, electric field strength within the second group III nitride (e.g., GaN channel layer 8) is weak. Accordingly, two-dimensional electron gas induced by the spontaneous polarization of the first AlN (in other words, positive charge of the nitrogen polar face) is broadly distributed within the second group III nitride. Thus, according to the semiconductor device of the first embodiment, the quantum confined transistor of which the channel layer and so forth are made of group III nitrides is able to be kept from becoming highly resistive.

### Second Embodiment

A semiconductor device according to a second embodiment resembles the semiconductor device according to the first embodiment. Accordingly, description of configurations and so forth that are the same as those in the first embodiment will be omitted or simplified.

### (1) Structure

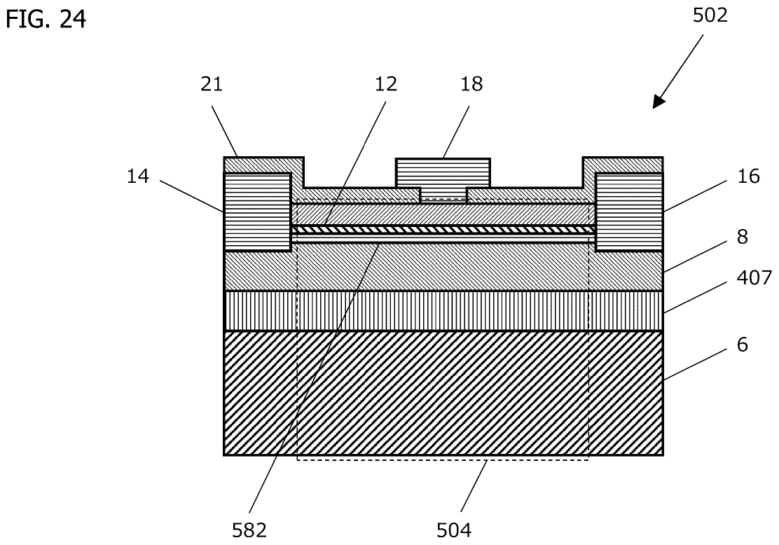

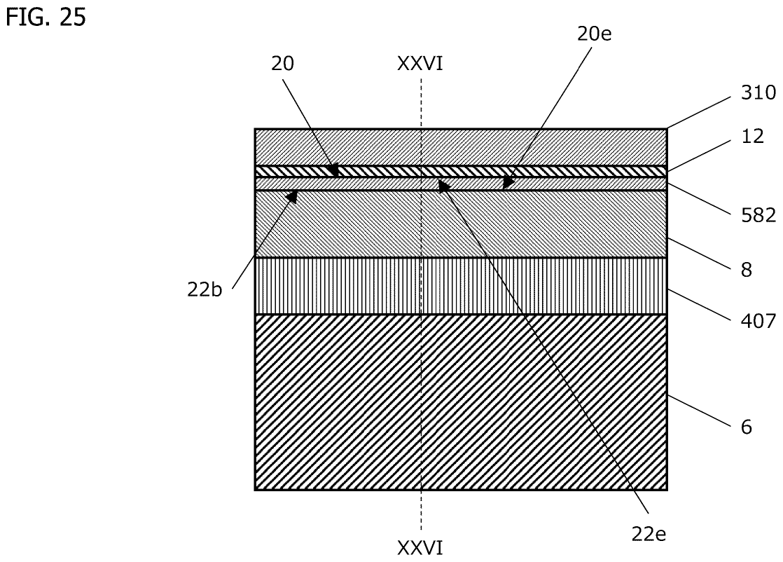

FIG. 24 is a cross-sectional view illustrating an example of the semiconductor device according to the second embodiment (hereinafter, referred to as “semiconductor device 502”). FIG. 25 is an enlarged view of a portion of FIG. 24 that is surrounded by a dashed line 504. In addition to the configuration of the semiconductor device 402 according to the first embodiment (see FIG. 12), the semiconductor device 502 further has a spacer layer 582 that is disposed between the GaN channel layer 8 and the Al polarity inversion layer 12 (see FIGS. 24 and 25).

The spacer layer 582 (see FIG. 25) is Alₓ₅Ga₁₋ₓ₅N (0.4≤x5≤1) that has a lower face 20e (hereinafter referred to as “fifth lower face”) that is a (0 0 0 1) face, and an upper face 22e (hereinafter referred to as “fifth upper face”) that is a (0 0 0 −1) face and that is disposed upward from the fifth lower face 20e, the spacer layer 582 having a bandgap that is broader than that of the GaN channel layer 8.

The spacer layer 582 is a layer that is sufficiently thinner than the InAlGaN cap layer 310. The thickness of the spacer layer 582 (hereinafter referred to as “AlGaN spacer layer”) is for instance, not less than 0.5 nm and not more than 2 nm (preferably 1 nm).

### (2) Energy Band

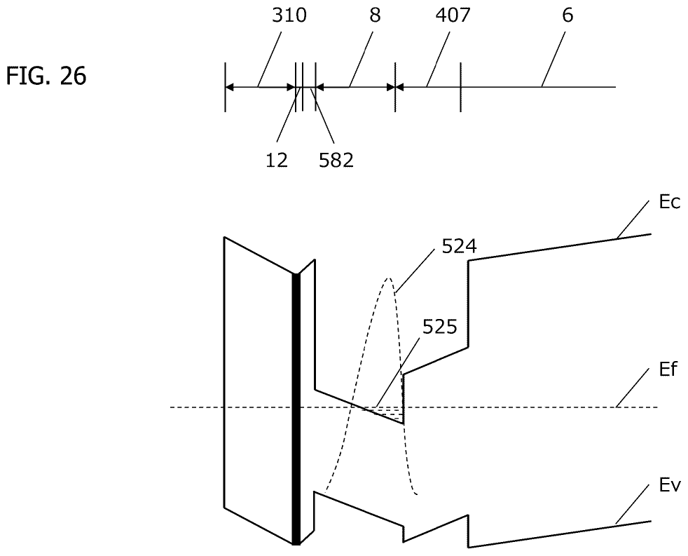

FIG. 26 is a band diagram taken along line XXVI-XXVI in FIG. 25. The orientation of spontaneous polarization of the AlGaN spacer layer 582 is the same as the orientation of spontaneous polarization of the AlN substrate 6. Accordingly, a conduction band lower end Ec within the AlGaN spacer layer 582 increases toward the GaN channel layer 8 (see FIG. 26). However, the AlGaN spacer layer 582 is thin, as described above, and accordingly the AlGaN spacer layer 582 only slightly pushes the conduction band lower end Ec at the second upper face 22b (see FIG. 25) of the GaN channel layer 8 upward.

The orientation of spontaneous polarization of the InAlGaN cap layer 310 is opposite to the orientation of spontaneous polarization of the AlN substrate 6. Accordingly, the conduction band lower end Ec within the InAlGaN cap layer 310 decreases toward the GaN channel layer 8. The AlGaN spacer layer 582 pushes the conduction band lower end Ec upward only slightly, as described above. Accordingly, the conduction band lower end Ec at the second upper face 22b of the GaN channel layer 8 is pushed downward by decrease (exactly, decrease toward the GaN channel layer 8) of the conduction band lower end Ec within the InAlGaN cap layer 310.

Accordingly, the inclination of the conduction band lower end Ec at the channel layer 8 becomes gradual. As a result, two-dimensional electron gas 525 is broadly distributed within the channel layer 8 (see distribution 524 of conduction band electrons). Accordingly, the GaN channel layer 8 is suppressed from being highly resistive.

The two-dimensional electron gas 525 within the GaN channel layer 8 is drawn away from the Al polarity inversion layer 12 by the AlGaN spacer layer 582. Accordingly, scattering of the two-dimensional electron gas 525 due to crystal defects (or crystal disturbances) in the Al polarity inversion layer 12 is suppressed, hence mobility in the GaN channel layer 8 increases. Thus, resistance of the channel layer 8 is low.

### (3) Manufacturing Method

The manufacturing method of the semiconductor device 502 resembles the manufacturing method of the semiconductor device 402 according to the first embodiment.

Note, however, that the Al polarity inversion layer 12 is grown following growing the AlGaN spacer layer 582 on the GaN channel layer 8, rather than growing the Al polarity inversion layer 12 directly on the GaN channel layer 8. That is to say, the AlGaN spacer layer 582 is grown between the channel layer 8 and the Al polarity inversion layer 12.

Also, when the InAlGaN cap layer 310 and so forth are etched to form the recesses for electrodes (see FIG. 16), the AlGaN spacer layer 582 is also etched along therewith.

Other than these processes, the manufacturing method of the semiconductor device 502 is almost the same as the manufacturing method of the semiconductor device 402 according to the first embodiment.

### (4) Method of Usage

The method of usage of the semiconductor device according to the second embodiment is almost the same as the method of usage of the semiconductor device according to the first embodiment (see “(7) Usage Examples”). Accordingly, description of the method of usage of the semiconductor device according to the second embodiment will be omitted.

The semiconductor device 502 described with reference to FIG. 24 and so forth has the AlGaN spacer layer 582. However, the semiconductor device according to the second embodiment may have a different group III nitride (e.g., InAlGaN) instead of the AlGaN spacer layer 582.

That is to say, in addition to the semiconductor device according to the first embodiment, the semiconductor device according to the second embodiment is a device that further includes a fifth group III nitride (e.g., AlGaN spacer layer 582) disposed between the second group III nitride (e.g., GaN channel layer 8) and the polarity inversion layer (e.g., Al polarity inversion layer 12).

The fifth group III nitride (e.g., AlGaN spacer layer 582) includes the fifth lower face 20e that is a (0 0 0 1) face, and the fifth upper face 22e that is a (0 0 0 −1) face and that is disposed upward from the fifth lower face 20e, the fifth group III nitride further having a bandgap that is broader than the bandgap of the second group III nitride (e.g., GaN channel layer 8).

Note, however, that the fifth group III nitride is a mixed crystal of AlN, which has the broadest bandgap of group III nitrides, and other group III nitrides (i.e., GaN and InN). Specifically, the fifth group III nitride is one of InAlGaN, AlGaN, InAlN, and AlN. That is to say, the fifth group III nitride is expressed by Inₓ₅Al_{y5}Ga_{1-x5-y5}N (0≤x5≤1−y5, 0<y5≤1).

The semiconductor device according to the second embodiment has the fifth group III nitride (e.g., spacer layer) between the second group III nitride (i.e., channel layer) and the polarity inversion layer, and accordingly scattering of the two-dimensional electron gas due to crystal defects (i.e., crystal disturbances) in the polarity inversion layer is suppressed. Thus, according to the semiconductor device of the second embodiment, mobility in the second group III nitride (i.e., channel layer) is improved.

While embodiments of the present invention have been described above, the first and second embodiments are exemplary and not restrictive. For instance, the semiconductor devices according to the first and second embodiments are transistors having a Schottky gate structure. However, the semiconductor device according to the present invention may be a transistor having a metal-insulator-semiconductor (MIS) gate structure.

The semiconductor devices according to the first and second embodiments are normally-on transistors. However, the semiconductor device according to the present invention may be a normally-off transistor that has a p-type GaN layer between the cap layer and the gate electrode, for instance. Alternatively, the semiconductor devices according to the first and second embodiments may be normally-off transistors in which the cap layer is thinned directly below the gate electrode.

The semiconductor devices according to the first and second embodiments are transistors. However, the semiconductor device according to the present invention may be a different semiconductor device, such as a gated-anode diode or the like, for instance. The gated-anode diode is a diode obtained by connecting the gate electrode of a normally-off transistor to the drain electrode thereof.

The layer structures of each of the electrodes described in the first and second embodiments are examples, and each of the electrodes may have other layer structures, regardless of whether single layer or multilayer. Also, the methods of forming each of the electrodes described in the first and second embodiments are examples as well, and the methods of forming the electrodes may be any other method. For instance, the heating treatment in the process of formation of the source electrode and the drain electrode may be omitted, as long as Ohmic properties are able to be obtained. In the same way, the gate electrode material may be heated as long as Schottky properties are able to be obtained.

In one aspect, according to the present invention, the direction of spontaneous polarization of the AlN on the lower side of the channel layer and the direction of spontaneous polarization of the group III nitride on the upper side of the channel layer are opposite to each other, and accordingly second-dimensional electron gas spreads within the channel layer, and the channel layer of the quantum confined transistor formed of the group III nitride is suppressed from becoming highly resistive.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a first AlN that includes a first lower face that is a (0 0 0 1) face, and a first upper face that is a (0 0 0 −1) face and is disposed upward from the first lower face, the first AlN being a substrate or a group III nitride on a substrate;
a second group III nitride that includes a second lower face that is a (0 0 0 1) face, and a second upper face that is a (0 0 0 −1) face and is disposed upward from the second lower face, the second group III nitride having a bandgap that is narrower than a bandgap of AlN, and the second group III nitride being disposed on or upward from the first AlN; and
a third group III nitride that includes a third lower face that is a (0 0 0-1) face, and a third upper face that is a (0 0 0 1) face and is disposed upward from the third lower face, the third group III nitride having a bandgap that is broader than a bandgap of the second group III nitride, and the third group III nitride being disposed upward from the second group III nitride, wherein
the second group III nitride is Inₓ₂Al_{y2}Ga_{1-x2-y2}N (0≤x2≤1−y2, 0≤y2<1),
the third group III nitride is Inₓ₃Al_{y3}Ga_{1-x3-y3}N (0≤x3≤1−y3, 0<y3≤1), and
a plurality of quantum levels are formed in a conduction band of the second group III nitride.

2. The semiconductor device according to claim 1, further comprising:
a polarity inversion layer that has a lower face and an upper face that is disposed upward from the lower face, and that is disposed between the second group III nitride and the third group III nitride, wherein
the polarity inversion layer is a layer on which a group III nitride including a bottom face is grown such that the bottom face comes into contact with the upper face, the bottom face being a (0 0 0 −1) face.

3. The semiconductor device according to claim 1, further comprising:
a fourth group III nitride that includes a fourth lower face that is a (0 0 0 1) face, and a fourth upper face that is a (0 0 0 −1) face and that is disposed upward from the fourth lower face, the fourth group III nitride having a bandgap that is broader than the bandgap of the second group III nitride and that is narrower than the bandgap of the AlN, the fourth group III nitride being disposed between the first AlN and the second group III nitride, wherein
the fourth group III nitride is Inₓ₄Al_{y4}Ga_{1-x4-y4}N (0≤x4≤1−y4, 0<y4≤1).

4. The semiconductor device according to claim 1, wherein
the second group III nitride is Inₓ₂Al_{y2}Ga_{1-x2-y2}N (0≤x2≤0.4, 0≤y2≤ 0.6), and
the third group III nitride is Inₓ₃Al_{y3}Ga_{1-x3-y3}N (0≤x3≤0.2, 0.4≤y3≤ 1−x3).

5. The semiconductor device according to claim 2, further comprising:
a fifth group III nitride that includes a fifth lower face that is a (0 0 0 1) face, and a fifth upper face that is a (0 0 0 −1) face and that is disposed upward from the fifth lower face, the fifth group III nitride having a bandgap that is broader than the bandgap of the second group III nitride, and the fifth group III nitride being disposed between the second group III nitride and the polarity inversion layer, wherein
the fifth group III nitride is Inₓ₅Al_{y5}Ga_{1-x5-y5}N (0≤x5≤1−y5, 0<y5≤ 1).

6. The semiconductor device according to claim 1, wherein the second group III nitride has a thickness that is not less than 5 nm and not more than 20 nm.

7. The semiconductor device according to claim 1, wherein the first AlN has a thickness of not less than 200 nm.

8. The semiconductor device according to claim 1, further comprising:
a drain electrode that a current that flows into the second group III nitride passes through, prior to the flowing into the second group III nitride;
a source electrode that the current passes through, following exiting the second group III nitride; and
a gate electrode that controls flow of the current.

9. The semiconductor device according to claim 2, wherein the polarity inversion layer is an Al film of not less than two atomic layers and not more than four atomic layers.

10. A manufacturing method for a semiconductor device, the manufacturing method comprising:
growing a second group III nitride including a second lower face that is a (0 0 0 1) face and a second upper face that is a (0 0 0 −1) face and is disposed upward from the second lower face, on or upward from a (0 0 0 −1) face of a first AlN, wherein the second group III nitride has a bandgap that is narrower than a bandgap of AlN;
growing a polarity inversion layer that includes a lower face and an upper face disposed upward from the lower face, on or upward from the second group III nitride, following the growing of the second group III nitride; and
growing a third group III nitride that includes a third lower face that is a (0 0 0 −1) face and a third upper face that is a (0 0 0 1) face and is disposed upward from the third lower face, on the polarity inversion layer, following the growing of the polarity inversion layer, wherein the third group III nitride has a bandgap that is broader than a bandgap of the second group III nitride, wherein
the second group III nitride is Inₓ₂Al_{y2}Ga_{1-x2-y2}N (0≤x2≤1−y2, 0≤y2<1),
the third group III nitride is Inₓ₃Al_{y3}Ga_{1-x3-y3}N (0≤x3≤1−y3, 0<y3≤1), and
the polarity inversion layer is a substance on which a group III nitride is grown, the group III nitride including a (0 0 0 −1) face that comes into contact with the upper face.
